(19) United States
(12) Patent Application Publication
(10) Pub. No.: US 2020/0052135 A1
(43) Pub. Date: Feb. 13, 2020

(54) PHOTOELECTRIC CONVERSION ELEMENT AND PHOTOELECTRIC CONVERSION ELEMENT MANUFACTURING METHOD

(71) Applicant: KANEKA CORPORATION, Osaka-shi, Osaka (JP)

(72) Inventor: Masanori FUKUDA, Toyooka-shi, Hyogo (JP)

(21) Appl. No.: 16/499,379

(22) PCT Filed: Mar. 28, 2018
(86) PCT No.: PCT/JP2018/012813

§ 371 Date: Sep. 30, 2019

(30) Foreign Application Priority Data
Mar. 31, 2017 (JP) 2017-072328

(51) Int. Cl. H01L 31/0224; H01L 31/075; H01L 31/18

(52) U.S. Cl. CPC H01L 31/022425; H01L 31/1876; H01L 31/075; H01L 31/022466

(57) ABSTRACT

A method of manufacturing a photoelectric conversion element according to the present disclosure includes the steps of: preparing a semiconductor substrate including an n-type semiconductor portion and a p-type semiconductor portion, which forms a diode together with the n-type semiconductor portion; forming an n-side underlying conductive layer on at least apart of the n-type semiconductor portion; forming a p-side underlying conductive layer on at least a part of the p-type semiconductor portion; immersing the n-side underlying conductive layer and the p-side underlying conductive layer in a plating solution; and forming plating layers on at least a part of the n-side underlying conductive layer and at least a part of the p-side underlying conductive layer by feeding electricity to the n-side underlying conductive layer, under a state in which the n-side underlying conductive layer and the p-side underlying conductive layer are electrically connected by the diode alone.

### TECHNICAL FIELD

The present invention relates to a photoelectric conversion element and a method of manufacturing a photoelectric conversion element.

### BACKGROUND ART

In Patent Literature 1 described below, there is disclosed a method of manufacturing a solar battery that includes steps described below. A photoelectric conversion layer is formed first, and a first transparent electrode layer is formed on a front surface and side surfaces of the photoelectric conversion layer. A second transparent electrode layer is then formed on aback surface of the photoelectric conversion layer and the side surfaces of the photoelectric conversion layer. A metal layer is then formed on the second transparent electrode layer. Abase electrode layer is then formed on the first transparent electrode layer. The underlying electrode layer and the metal layer are then immersed in a plating solution, and electricity is fed from the metal layer side, to thereby plate the underlying electrode layer, which is electrically connected to the metal layer on the photoelectric conversion layer side, and the metal layer at the same time. Portions of the first transparent electrode layer, the second transparent electrode layer, the metal layer, and the underlying electrode layer that are formed on the side surfaces of the photoelectric conversion layer are then removed.

### CITATION LIST

### Patent Literature

[PTL 1] JP 2015-82603 A

### SUMMARY OF INVENTION

### Technical Problem

However, low manufacturing efficiency is a problem with the method of manufacturing a solar battery of the related art. That is, the manufacturing method of the related art described above requires a step of ultimately removing the portions of the first transparent electrode layer, the second transparent electrode layer, the metal layer, and the underlying electrode layer that are formed on the side surfaces of the photoelectric conversion layer in order to avoid a short circuit between the electrodes that are formed on the front surface and back surface of the photoelectric conversion layer and that are connected to each other on the side surfaces of the photoelectric conversion layer, which results in low manufacturing efficiency.

The present invention has been made in view of the above-mentioned problem, and an object of the present invention is to improve manufacturing efficiency of the photoelectric conversion element.

### Solution to Problem

(1) A method of manufacturing a photoelectric conversion element according to the present disclosure includes the steps of: preparing a semiconductor substrate including an n-type semiconductor portion and a p-type semiconductor portion, which forms a diode together with the n-type semiconductor portion; forming an n-side underlying conductive layer on at least apart of the n-type semiconductor portion; forming a p-side underlying conductive layer on at least a part of the p-type semiconductor portion; immersing the n-side underlying conductive layer and the p-side underlying conductive layer in a plating solution; and forming plating layers on at least a part of the n-side underlying conductive layer and at least a part of the p-side underlying conductive layer by feeding electricity to the n-side underlying conductive layer, under a state in which the n-side underlying conductive layer and the p-side underlying conductive layer are electrically connected by the diode alone.

(2) In the above-mentioned method of manufacturing the photoelectric conversion element, the photoelectric conversion element has a first principal surface and a second principal surface opposed to the first principal surface, the n-type semiconductor portion is formed on the first-principal-surface side of the semiconductor substrate, the p-type semiconductor portion is formed on the second-principal-surface side of the semiconductor substrate, in the step of forming the n-side underlying conductive layer, the n-side underlying conductive layer is formed on the first-principal-surface side of the n-type semiconductor portion, in the step of forming the p-side underlying conductive layer, the p-side underlying conductive layer is formed on the second-principal-surface side of the p-type semiconductor portion, and in the step of forming the plating layers, the plating layers may be formed on the first-principal-surface side of the n-side underlying conductive layer and the second-principal-surface side of the p-side underlying conductive layer.

(3) In the above-mentioned method of manufacturing the photoelectric conversion element, the n-type semiconductor portion and the p-type semiconductor portion may be formed on the same principal-surface side of the semiconductor substrate.

(4) In the above-mentioned method of manufacturing the photoelectric conversion element, in the step of forming then-side underlying conductive layer, the n-side underlying conductive layer may be formed using a transparent electrode layer.

(5) In the above-mentioned method of manufacturing the photoelectric conversion element, in the step of forming the p-side underlying conductive layer, the p-side underlying conductive layer may be formed using a transparent electrode layer.

(6) In the above-mentioned method of manufacturing the photoelectric conversion element, in the step of forming the p-side underlying conductive layer, the p-side underlying conductive layer may be formed thicker than the n-side underlying conductive layer, or, in the step of forming the n-side underlying conductive layer, then-side underlying conductive layer may be formed thinner than the p-side underlying conductive layer.

(7) In the above-mentioned method of manufacturing the photoelectric conversion element, in the step of forming the plating layers, the plating layer to be formed on the n-side underlying conductive layer may be formed thicker than the plating layer to be formed on the p-side underlying conductive layer.

(8) In the above-mentioned method of manufacturing the photoelectric conversion element, in the step of preparing the semiconductor substrate, the semiconductor substrate having an intrinsic semiconductor portion between the n-type semiconductor portion and the p-type semiconductor portion may be prepared, and the p-type semiconductor portion, the intrinsic semiconductor portion, and the n-type semiconductor portion may form a PIN junction diode.

(9) In the above-mentioned method of manufacturing the photoelectric conversion element, the method may further include, before the step of forming the n-side underlying conductive layer, a step of forming a first transparent electrode layer on the n-type semiconductor portion.

(10) In the above-mentioned method of manufacturing the photoelectric conversion element, the method may further include, before the step of forming the p-side underlying conductive layer, forming a second transparent electrode layer on the p-type semiconductor portion.

(11) In the above-mentioned method of manufacturing the photoelectric conversion element, the method may further include, after the step of forming the n-side underlying conductive layer, a step of forming a first insulating layer on the n-type semiconductor portion.

(12) In the above-mentioned method of manufacturing the photoelectric conversion element, the method may further include, after the step of forming the p-side underlying conductive layer, a step of forming a second insulating layer on the p-type semiconductor portion.

(13) A photoelectric conversion element according to this disclosure includes: a semiconductor substrate including an n-type semiconductor portion and a p-type semiconductor portion, which forms a diode together with the n-type semiconductor portion; an n-side underlying conductive layer provided on at least a part of the n-type semiconductor portion; a p-side underlying conductive layer provided on at least a part of the p-type semiconductor portion; a first plating layer provided on at least a part of the n-side underlying conductive layer; and a second plating layer provided on at least a part of the p-side underlying conductive layer, the first plating layer being thicker than the second plating layer, the n-side underlying conductive layer being thinner than the p-side underlying conductive layer.

(14) In the above-mentioned photoelectric conversion element, the photoelectric conversion element may have a first principal surface and a second principal surface opposed to the first principal surface, the n-type semiconductor portion may be provided on the first-principal-surface side of the semiconductor substrate, the p-type semiconductor portion may be provided on the second-principal-surface side of the semiconductor substrate, the n-side underlying conductive layer may be provided on the first-principal-surface side of the n-type semiconductor portion, the p-side underlying conductive layer may be provided on the second-principal-surface side of the p-type semiconductor portion, the first plating layer may be provided on the first-principal-surface side of the n-side underlying conductive layer, and the second plating layer may be provided on the second-principal-surface side of the p-side underlying conductive layer.

(15) In the above-mentioned photoelectric conversion element, the n-type semiconductor portion and the p-type semiconductor portion may be provided on the same principal-surface side of the semiconductor substrate.

(16) In the above-mentioned photoelectric conversion element, the n-side underlying conductive layer may include a transparent electrode layer.

(17) In the above-mentioned photoelectric conversion element, the p-side underlying conductive layer may include a transparent electrode layer.

(18) In the above-mentioned photoelectric conversion element, the semiconductor substrate may have an intrinsic semiconductor portion between the n-type semiconductor portion and the p-type semiconductor portion, the p-type semiconductor portion, the intrinsic semiconductor portion, and the n-type semiconductor portion may form a PIN junction diode.

(19) The photoelectric conversion element may further include a first transparent electrode layer, which is provided between the n-side base conductive layer and the n-type semiconductor portion.

(20) The above-mentioned photoelectric conversion element may further include a second transparent electrode layer, which is provided between the p-side underlying conductive layer and the p-type semiconductor portion.

(21) The above-mentioned photoelectric conversion element may further include a first insulating layer, which is provided on the first transparent electrode layer.

(22) The above-mentioned photoelectric conversion element may further include a second insulating layer, which is provided on the second transparent electrode layer.

### BRIEF DESCRIPTION OF DRAWINGS

FIG. 1 is a plan view for illustrating the front side of a photoelectric conversion element according to a first embodiment of the present disclosure.

FIG. 2 is a plan view for illustrating the back side of the photoelectric conversion element according to the first embodiment.

FIG. 3 is a sectional view taken along the line III-III of FIG. 1.

FIG. 4 is a sectional view for illustrating a method of manufacturing a photoelectric conversion element according to the first embodiment.

FIG. 5 is a sectional view for illustrating the method of manufacturing a photoelectric conversion element according to the first embodiment.

FIG. 6 is a sectional view for illustrating the method of manufacturing a photoelectric conversion element according to the first embodiment.

FIG. 7 is a sectional view for illustrating the method of manufacturing a photoelectric conversion element according to the first embodiment.

FIG. 8 is a sectional view for illustrating the method of manufacturing a photoelectric conversion element according to the first embodiment.

FIG. 9 is a conceptual diagram for illustrating a step of forming a first plating layer and a second plating layer.

FIG. 10 is a sectional view of a photoelectric conversion element according to another example of the first embodiment.

FIG. 11 is a sectional view of a photoelectric conversion element according to still another example of the first embodiment.

### DESCRIPTION OF EMBODIMENTS

A first embodiment of the present disclosure is described below with reference to the accompanying drawings.

[Photoelectric Conversion Element 100]

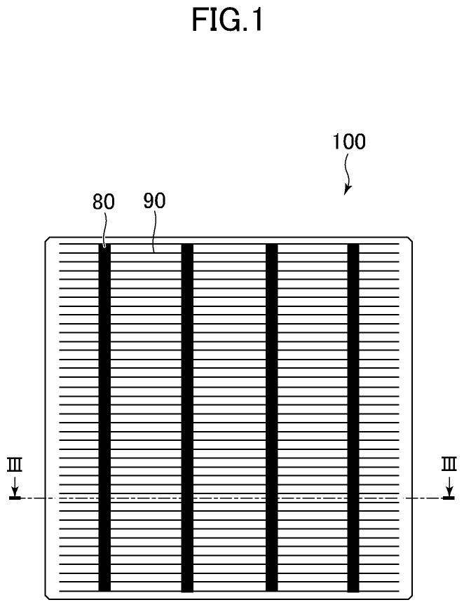

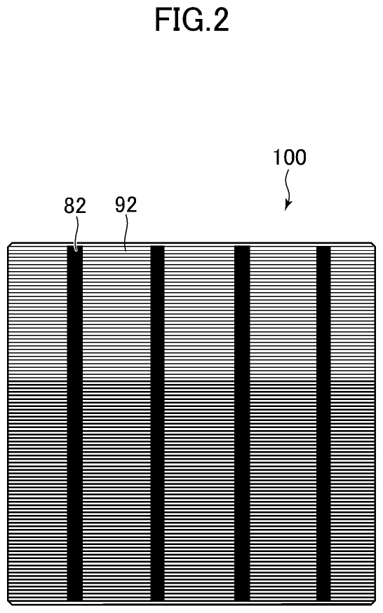

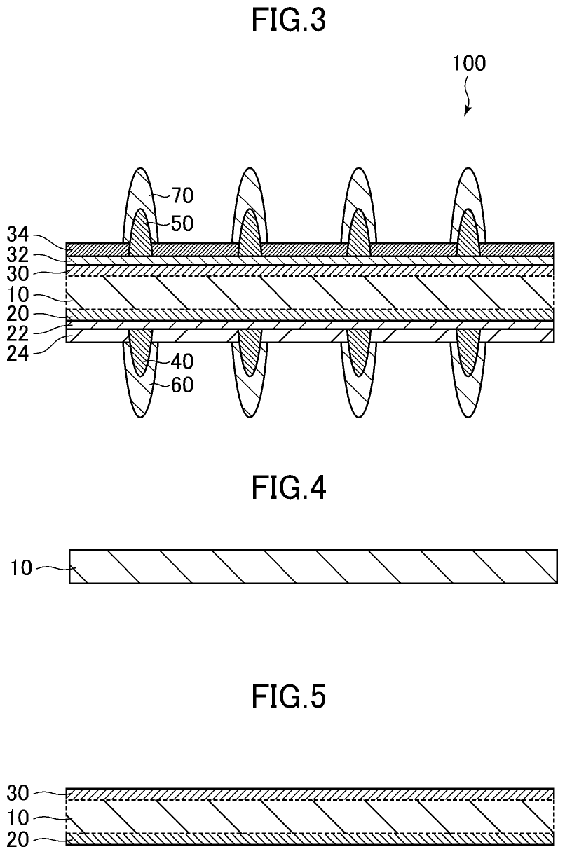

FIG. 1 is a plan view for illustrating the front side (incident-surface side) of a photoelectric conversion element 100 according to the first embodiment. FIG. 2 is a plan view for illustrating the back side of the photoelectric conversion element 100 according to the first embodiment. FIG. 3 is a sectional view taken along the line III-III of FIG. 1.

As illustrated in FIG. 1 and FIG. 2, the photoelectric conversion element 100 has, on its front surface and back surface, a plurality of bus bar electrodes denoted by 80 and 82, and a large number of finger electrodes denoted by 90 and 92 formed so as to intersect with the bus bar electrodes 80 and 82. In the present disclosure, the back surface of the photoelectric conversion element 100 is defined as a first principal surface and the front surface of the photoelectric conversion element 100 is defined as a second principal surface.

As illustrated in FIG. 3, the photoelectric conversion element 100 according to the first embodiment includes a semiconductor substrate 10. The semiconductor substrate 10 has an n-type semiconductor portion 20 on the first-principal-surface side. The semiconductor substrate 10 has a p-type semiconductor portion 30 on the second-principal-surface side. In FIG. 3, the first-principal-surface side is shown as the lower side of the drawing, and the second-principal-surface side is shown as the upper side of the drawing.

A PN junction is formed between the n-type semiconductor portion 20 and the p-type semiconductor portion 30.

In the example illustrated in FIG. 3, boundary lines are drawn between the semiconductor substrate 10 and the n-type semiconductor portion 20 and between the semiconductor substrate and the p-type semiconductor portion 30. Another configuration may be employed in which the semiconductor substrate 10 itself is an n-type semiconductor or a p-type semiconductor, and accordingly no boundary is provided between the semiconductor substrate 10 and the n-type semiconductor portion 20, or between the semiconductor substrate 10 and the p-type semiconductor portion 30.

On the first-principal-surface side in the n-type semiconductor portion 20, an n-side underlying conductive layer 40 is formed in regions for forming the bus bar electrodes 82. On the second-principal-surface side in the p-type semiconductor portion 30, a p-side underlying conductive layer 50 is formed in regions for forming the bus bar electrodes 80.

A first plating layer 60 is further formed on the first-principal-surface side in then-side underlying conductive layer 40. A second plating layer 70 is further formed on the second-principal-surface side in the p-type underlying conductive layer 50.

The first plating layer 60 and the n-side underlying conductive layer 40 are configured to form the bus bar electrodes 82, which are illustrated in FIG. 2 and serve as back-side bus bar electrodes. The second plating layer 70 and the p-side underlying conductive layer 50 are configured to form the bus bar electrodes 80, which are illustrated in FIG. 1 and serve as front-side bus bar electrodes.

In the first embodiment, the first plating layer 60 formed on the first-principal-surface side is thicker than the second plating layer 70 formed on the second-principal-surface side. The n-side underlying conductive layer 40 formed on the first-principal-surface side is thinner than the p-type underlying conductive layer 50 formed on the second-principal-surface side. The thicknesses of the respective layers may be obtained by observing sections of the electrodes with an electron microscope and measuring lengths that correspond to the thicknesses of the plating layers.

In the configuration of the first embodiment, the semiconductor substrate 10 is an n-type semiconductor substrate. A first transparent electrode layer 22 and a first insulating layer 24, which is formed on the first-principal-surface side of the first transparent electrode layer 22, are further included between the n-side underlying conductive layer 40 and the n-type semiconductor portion 20. A second transparent electrode layer 32 and a second insulating layer 34, which is formed on the second-principal-surface side of the second transparent electrode layer 32, are further included between the p-type underlying conductive layer 50 and the p-type semiconductor portion 30.

The first embodiment may have a configuration in which an intrinsic semiconductor layer is interposed between the semiconductor substrate 10 and the n-type semiconductor portion 20, or a configuration in which an intrinsic semiconductor layer is interposed between the semiconductor substrate 10 and the p-type semiconductor portion 30. When an intrinsic semiconductor layer is interposed between the semiconductor substrate 10 and the n-type semiconductor portion 20, or between the semiconductor substrate 10 and the p-type semiconductor portion 30, a PIN junction is formed between the n-type semiconductor portion 20 and the p-type semiconductor portion 30. In the present disclosure, the PIN junction is included in the PN junction described above.

[Method of Manufacturing Photoelectric Conversion Element 100]

A method of manufacturing a photoelectric conversion element 100 according to this embodiment is described with reference to FIG. 3 to FIG. 9. FIG. 3 to FIG. 8 each are sectional views taken along the line III-III of FIG. 1.

[Semiconductor Substrate 10 Preparation Step]

As illustrated in FIG. 4, the semiconductor substrate 10 is prepared first. A silicon substrate, for example, a single-crystal silicon substrate or a polycrystalline silicon substrate may be used as the semiconductor substrate 10. A single-crystal silicon substrate is preferred because of the long life of carriers in the crystalline substrate. As the silicon substrate to be used, an n-type crystal silicon substrate or a p-type crystal silicon substrate may be used. An n-type single-crystal silicon substrate is particularly preferred because of the long life of carriers in the crystalline substrate. This is because, while light-induced degradation (LID) in which light irradiation causes boron (B) as a p-type dopant to form a recombination center may occur in p-type single-crystal silicon, the use of an n-type single-crystal silicon substrate as the semiconductor substrate 10 keeps LID from occurring. In this embodiment, an n-type single-crystal silicon substrate is used as the semiconductor substrate 10.

It is preferred for the single-crystal silicon substrate to be used as the semiconductor substrate 10 to have a thickness of 50 μm to 300 μm. A thickness of 60 μm to 200 μm is more preferred, and a thickness of 70 μm to 180 μm is even more preferred. The material cost can be lowered more with use of a substrate that has a thickness in this range.

The semiconductor substrate 10 is preferred to have a concave-convex structure called a texture structure on its incident side from the viewpoint of optical confinement.

It is preferred for the semiconductor substrate 10 to have passivation layers on the first-principal-surface side and the second-principal-surface side. The passivation layers may be of any type as long as the passivation layers are capable of suppressing carrier recombination and terminating surface defects. However, intrinsic semiconductor layers, particularly intrinsic amorphous silicon layers, are preferred as the passivation layers.

[Step of Forming n-Type Semiconductor Portion 20]

As illustrated in FIG. 5, the n-type semiconductor portion 20 is formed next on the first-principal-surface side, namely, the back side, of the semiconductor substrate 10.

Materials used to form the n-type semiconductor portion 20 desirably include an amorphous silicon layer containing an amorphous silicon component, for example, an amorphous silicon film or a microcrystalline silicon. Phosphorus (P) or the like may be used as dopant impurity.

How the n-type semiconductor portion 20 is formed is not particularly limited and chemical vapor deposition (CVD), for example, may be used. In the case of using CVD, SiH₄ gas is used and PH₃ diluted with hydrogen is preferred as gas doped with a dopant. A minute dose of dopant impurity is sufficient, and mixture gas diluted with SiH₄ or H₂ in advance is accordingly preferred. In the film forming of the n-type semiconductor portion 20, gas containing a heterogeneous element, such as CH₄, CO₂, NH₃, and GeH₄, may be added to alloy a silicon-based thin film and to thereby change an energy gap of the silicon-based thin film. A minute dose of oxygen, carbon, or similar impurity may also be added in order to improve the transmittivity of light. This is accomplished by introducing CO₂, CH₄, or similar gas during the film forming by CVD.

When a p-type polycrystalline silicon substrate is used as the semiconductor substrate 10, the n-type semiconductor portion 20 is formed by diffusing an n-type dopant on the first-principal-surface side of the semiconductor substrate 10 and thus giving the n-type conductivity to the first-principal-surface side.

[Step of Forming p-Type Semiconductor Portion 30]

Further, as illustrated in FIG. 5, the p-type semiconductor portion 30 is formed on the second-principal-surface side, namely, the back side, of the semiconductor substrate 10. The step of forming the p-type semiconductor portion 30 may be executed before or after the step of forming the n-type semiconductor portion 20 described above.

Materials to be used to form the p-type semiconductor portion 30 desirably include an amorphous silicon layer containing an amorphous silicon component, for example, an amorphous silicon film or a microcrystalline silicon (a thin film containing amorphous silicon and crystalline silicon). Boron (B) or the like may be used as a dopant impurity.

How the p-type semiconductor portion 30 is formed is not particularly limited and CVD, for example, may be used. In the case of using CVD, SiH₄ gas is used and B₂H₆ diluted with hydrogen is preferred as gas doped with a dopant. A minute dose of dopant impurity is sufficient, and a mixture gas diluted with SiH₄ or H₂ in advance is accordingly preferred. In the film forming of the p-type semiconductor portion 30, gas containing a heterogeneous element, such as CH₄, CO₂, NH₃, and GeH₄, may be added to alloy a silicon-based thin film and to thereby change an energy gap of the silicon-based thin film. A minute dose of oxygen, carbon, or similar impurity may also be added in order to improve the transmittivity of light. This is accomplished by introducing CO₂, CH₄, or similar gas during the film forming by CVD.

When a p-type polycrystalline silicon substrate is used as the semiconductor substrate 10, the second-principal-surface side of the semiconductor substrate 10 has already turned into the p-type semiconductor portion 30, which is contained in the semiconductor substrate 10. The step of forming the p-type semiconductor portion 30 is not required in this case.

[Steps of forming First Transparent Electrode Layer 22 and Second Transparent Electrode Layer 32]

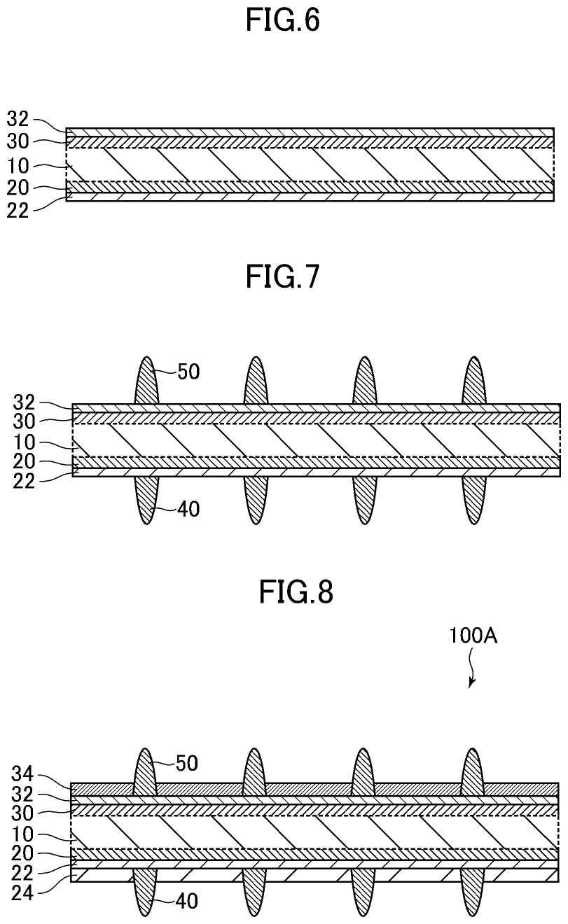

As illustrated in FIG. 6, sputtering, MOCVD, or a similar method is used next to form the first transparent electrode layer 22 on the first-principal-surface side of the n-type semiconductor portion 20, and to form the second transparent electrode layer on the second-principal-surface side of the p-type semiconductor portion 30. The step of forming the first transparent electrode layer 22 is only required to be executed after the step of forming the n-type semiconductor portion 20, and may precede the step of forming the p-type semiconductor portion 30. The step of forming the second transparent electrode layer 32 is only required to be executed after the step of forming the p-type semiconductor portion 30, and may precede the step of forming the n-type semiconductor portion 20.

Component materials of the first transparent electrode layer 22 and the second transparent electrode layer 32 are transparent conductive metal oxides, examples of which include indium oxide, zinc oxide, tin oxide, titanium oxide, and a complex oxide of those materials. A non-metal transparent conductive material, for example, graphene may also be used. Of the examples of the component given above, an indium-based complex oxide having indium oxide as a main component is preferred for the first transparent electrode layer 22 and the second transparent electrode layer 32 from the viewpoint of high conductivity and transparency. It is also preferred to use indium oxide doped with a dopant in order to secure reliability and even higher conductivity. Examples of impurity used as the dopant include Sn, W, Ce, Zn, As, Al, Si, S, and Ti.

[Steps of forming n-side Underlying Conductive Layer 40 and P-side Underlying Conductive Layer 50]

Next, as illustrated in FIG. 7, the n-side underlying conductive layer 40 is formed in the regions for forming the bus bar electrodes 82 on the first-principal-surface side of the first transparent electrode layer 22, and the p-side underlying conductive layer 50 is formed in the regions for forming the bus bar electrodes 80 on the second-principal-surface side of the second transparent electrode layer 32. The n-side underlying conductive layer 40 and the p-side underlying conductive layer 50 are layers that function as conductive underlying layers in a step of forming the first plating layer 60 and the second plating layer 70, which is described later, and are layers that serve as electrodes on which components of the first plating layer 60 and the second plating layer 70 precipitate.

The step of forming the n-side underlying conductive layer 40 is executed after the step of forming the n-type semiconductor portion 20 and, in the case of forming the first transparent electrode layer 22, after the step of forming the first transparent electrode layer 22. The step of forming the n-side underlying conductive layer 40 may precede the step of forming the p-type semiconductor portion 30. The step of forming the p-side underlying conductive layer 50 is executed after the step of forming the p-type semiconductor portion 30 and, in the case of forming the second transparent electrode layer 32, after the step of forming the second transparent electrode layer 32. The step of forming the p-side underlying conductive layer 50 may precede the step of forming the n-type semiconductor portion 20.

A material that may be used for the n-side underlying conductive layer 40 and the p-side underlying conductive layer 50 is, for example, Ni, Cu, Ag, Au, Pt, or an alloy of those elements. However, the n-side underlying conductive layer 40 and the p-side underlying conductive layer 50 are not limited to a particular material as long as the conductivity of the material is high enough to be functional as an underlying layer in electrolytic plating. Then-side underlying conductive layer 40 and the p-side underlying conductive layer 50 are preferred to have a volume resistivity of 10⁻⁴ Ω·cm or more and 10⁻² Ω·cm or less. A volume resistivity within this range enables the n-side underlying conductive layer 40 and the p-side underlying conductive layer 50 to satisfactorily function as conductive underlying layers. In the first embodiment, the n-side underlying conductive layer 40 and the p-side underlying conductive layer 50 are higher in conductivity than the first transparent electrode layer 22 and the second transparent electrode layer 32.

The n-side underlying conductive layer 40 and the p-side underlying conductive layer 50 may be formed by, for example, an ink jet method, screen printing, conductive wire bonding, spraying, vacuum evaporation, sputtering, electrolytic plating, or electroless plating. It is preferred from the viewpoint of cost and mass-producibility to print by screen printing with a paste that contains the material of the underlying conductive layers given above.

In the first embodiment, the n-side underlying conductive layer 40 is thinner than the p-side underlying conductive layer 50. This thickness relationship reduces the difference in thickness between the bus bar electrodes 80 and the bus bar electrodes 82, which are formed in the step of forming the first plating layer 60 and the second plating layer 70 described later.

An unfinished photoelectric conversion element 100A, in which the n-side underlying conductive layer 40 and the p-side underlying conductive layer 50 have been formed, is a diode with respect to a perpendicular direction of its principal surface, and a direction from the p-side underlying conductive layer 50 to the n-side underlying conductive layer 40 is the forward direction of the diode.

[Steps of forming First Insulating Layer 24 and Second Insulating Layer 34]

Next, as illustrated in FIG. 8, the first insulating layer 24 is formed on the first-principal-surface side of the first transparent electrode layer 22, and the second insulating layer 34 is formed on the second-principal-surface side of the second transparent electrode layer 32. The step of forming the first insulating layer 24 is only required to be executed after the step of forming the n-side underlying conductive layer 40, and may precede the step of forming the p-type semiconductor portion 30. The step of forming the second insulating layer 34 is only required to be executed after the step of forming the p-side underlying conductive layer 50, and may precede the step of forming the n-type semiconductor portion 20.

The first insulating layer 24 and the second insulating layer 34 may be formed from layers that are removable when a given condition is fulfilled, for example, layers of a photoresist material. When the first insulating layer 24 and the second insulating layer 34 are formed from a photoresist material, irradiation of light causes a structural change that allows a particular chemical to easily dissolve the first insulating layer 24 and the second insulating layer 34.

In the first embodiment, the first insulating layer 24 and the second insulating layer 34 are formed from a material that has chemical stability with respect to a plating solution to be used in the step of forming the first plating layer 60 and the second plating layer 70 described later. Use of this material makes the first insulating layer 24 and the second insulating layer 34 hard to dissolve and suppresses damage to the semiconductor substrate 10, the n-type semiconductor portion 20, and the p-type semiconductor portion 30 in the step of forming the first plating layer 60 and the second plating layer 70.

The photoresist material used to form the first insulating layer 24 and the second insulating layer 34 is not particularly limited as long as the photoresist material has the properties described above. Examples of usable photoresist materials include novolac resin and phenol resin in the case of a positive photoresist, and acrylic resin in the case of a negative photoresist.

A remover liquid to be used to remove the first insulating layer 24 and the second insulating layer 34 is, for example, a solution containing tetramethylammonium hydroxide, alkyl benzene sulfonic acid, ethanolamines, or sodium hydroxide.

In the first embodiment, a novolac resin, which is a positive photoresist, is used as a photoresist material and a sodium hydroxide aqueous solution is used as a remover liquid.

The first insulating layer 24 and the second insulating layer 34 may be formed from inorganic insulating films made of SiO, SiN, SiON, or a similar material. The method of forming the inorganic insulating films is not particularly limited, but CVD in which the thickness of a film can be controlled with precision is preferred. By CVD, the thickness of a film can be controlled by controlling material gas and film forming conditions.

[Step of Forming First Plating Layer 60 and Second Plating Layer 70]

Next, as illustrated in FIG. 3, the first plating layer 60 is formed on the first-principal-surface side of the n-side underlying conductive layer 40, and the second plating layer 70 is formed on the second-principal-surface side of the p-side underlying conductive layer 50. The step of forming the first plating layer 60 and the second plating layer 70 is executed after the steps of forming the n-side underlying conductive layer 40 and the p-side underlying conductive layer 50.

A material that may be used for the first plating layer 60 and the second plating layer 70 is, for example, Ni, Cu, Ag, Au, Pt, or an alloy of those elements. From the viewpoint of cost, Cu is particularly preferred.

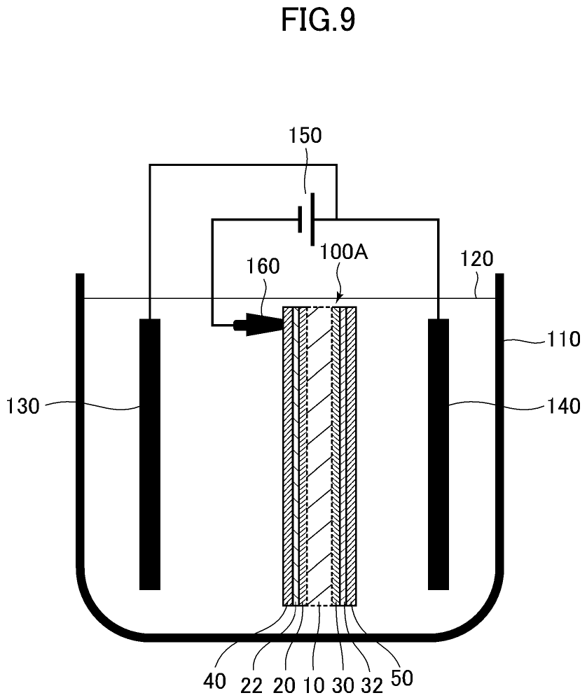

FIG. 9 is a conceptual diagram for illustrating the step of forming the first plating layer 60 and the second plating layer 70.

As illustrated in FIG. 9, the unfinished photoelectric conversion element 100A after the steps of forming the first insulating layer 24 and the second insulating layer 34 is immersed in a plating solution 120 inside a plating tank 110. The plating solution 120 is obtained by, for example, dissolving a metal salt. Specifically, a copper sulfate aqueous solution in which copper sulfate is dissociated, or a similar solution may be used as the plating solution 120. That is, in the first embodiment, copper ions and sulfate ions are dissociated in the plating solution 120. In FIG. 9, a side surface of the unfinished photoelectric conversion element 100A that is orthogonal to the section illustrated in FIG. 8 is shown.

A first plating electrode 130 and a second plating electrode 140, which are each a conductor shaped like a flat board, are placed in the plating tank 110. The first plating electrode 130 is arranged to face the n-side underlying conductive layer 40, and the second plating electrode 140 is arranged to face the p-side underlying conductive layer 50. The first plating electrode 130 and the second plating electrode 140 are formed from a single metal or a metal alloy that is used in electrolytic plating. In the first embodiment, copper or a copper alloy can be used for the first plating electrode 130 and the second plating electrode 140 because copper sulfate is used in the plating solution 120.

The first plating electrode 130 and the second plating electrode 140 are connected to a positive pole of a power source 150, and are accordingly anodes. The first plating electrode 130 and the second plating electrode 140 each have a size large enough to cover substantially the entirety of one surface of the semiconductor substrate 10.

An electricity feeding member 160 is connected to a negative pole of the power source 150, and electricity is fed to the n-side underlying conductive layer 40 via the electricity feeding member 160. During feeding, the n-side underlying conductive layer 40 and the p-side underlying conductive layer 50 are electrically connected solely by a diode that includes the n-type semiconductor portion 20 and the p-type semiconductor portion 30.

This is a state in which three conditions given below are fulfilled.

(1) The n-side underlying conductive layer 40 and the p-side underlying conductive layer 50 are not electrically connected by a conductive layer or the like that is not required to the configuration of the photoelectric conversion element 100.

(2) When an electric potential is applied so that the electric potential of the p-side underlying conductive layer 50 with respect to the n-side underlying conductive layer 40 is equal to or higher than a forward drop voltage, an electric current is caused to flow to the p-side underlying conductive layer 50 via a diode that includes the n-side underlying conductive layer 40 and the p-side underlying conductive layer 50.

(3) No electricity feeding member that is equipotential to the electricity feeding member 160 is connected to the p-side underlying conductive layer 50.

Through feed of the electricity from the side of the n-side underlying conductive layer 40, the first plating layer 60 illustrated in FIG. 3 is formed on an exposed surface of the n-side underlying conductive layer 40. The electric current also flows between the n-type semiconductor portion 20 and p-type semiconductor portion 30 described above in the forward direction of the diode, and the second plating layer 70 illustrated in FIG. 3 is accordingly formed at the same time on an exposed surface of the p-side underlying conductive layer 50.

Through this manufacturing method, the first plating layer 60 and the second plating layer 70 can be formed at the same time on the n-side underlying conductive layer 40 and the p-side underlying conductive layer 50, respectively, without forming a conductive layer unnecessary to the configuration of the photoelectric conversion element 100. It is consequently not required to provide a step of removing the unnecessary conductive layer after the step of forming the first plating layer 60 and the second plating layer 70, which means that the photoelectric conversion element 100 can be obtained at a high manufacturing efficiency.

The diode that includes the n-type semiconductor portion 20 and the p-type semiconductor portion 30 has a PN junction in the example described in the first embodiment. However, an intrinsic semiconductor portion may be interposed between the n-type semiconductor portion 20 and the p-type semiconductor portion 30, and a diode that includes the n-type semiconductor portion 20, the intrinsic semiconductor portion, and the p-type semiconductor portion 30 may have a PIN junction.

In the step of forming the first plating layer 60 and the second plating layer 70, electricity is fed from the side of the n-side underlying conductive layer 40, and the first plating layer 60, which is formed on an exposed surface of the n-side underlying conductive layer 40, is formed faster than the second plating layer 70, which is formed on an exposed surface of the p-side underlying conductive layer 50. The first plating layer 60 is thicker than the second plating layer 70 as a result. Meanwhile, the n-side underlying conductive layer 40 is formed thinner than the p-side underlying conductive layer 50 in the steps of forming then-side underlying conductive layer 40 and the p-side underlying conductive layer 50 as described above. This thickness relationship reduces the difference in thickness between the bus bar electrodes 80, which include the first plating layer 60 and the n-side underlying conductive layer 40, and the bus bar electrodes 82, which include the second plating layer 70 and the p-side underlying conductive layer 50.

In the example described above with reference to FIG. 3 and other drawings, the first transparent electrode layer 22 and the n-side underlying conductive layer 40 are formed on the first-principal-surface side of then-type semiconductor portion 20, whereas the second transparent electrode layer 32 and the p-side underlying conductive layer 50 are formed on the second-principal-surface side of the p-type semiconductor portion 30. However, the present disclosure is not limited to this example.

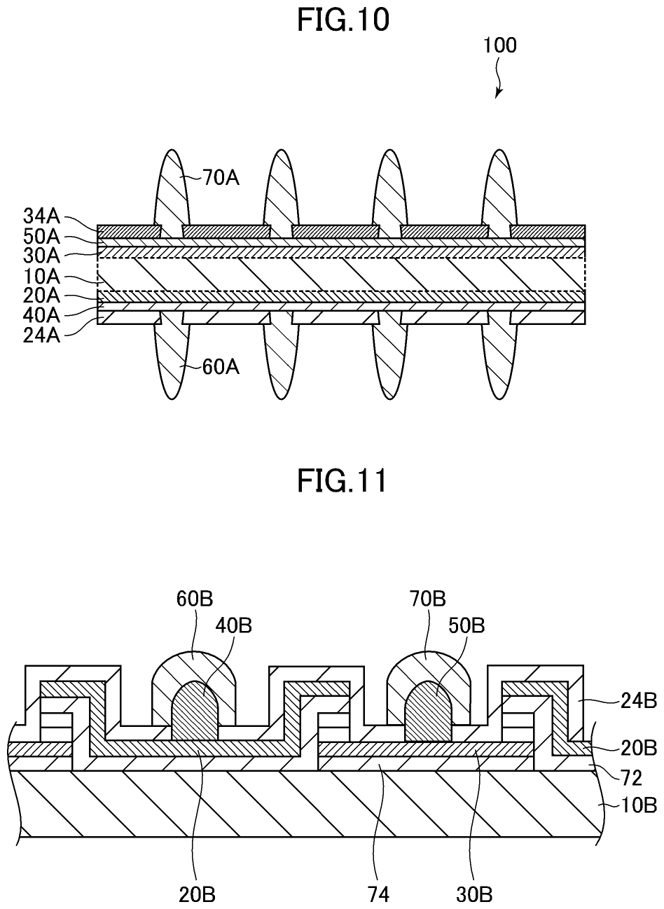

For instance, a configuration illustrated in FIG. 10 may be employed in which an n-side underlying conductive layer 40A is formed from a transparent electrode layer on the first-principal-surface side of an n-type semiconductor portion 20A, and a p-side underlying conductive layer 50A is formed from a transparent electrode layer on the second-principal-surface side of a p-type semiconductor portion 30A. Then-side underlying conductive layer 40A and the p-side underlying conductive layer 50A may be formed by the same method that is described above as a method to be used in the steps of forming the first transparent electrode layer 22 and the second transparent electrode layer 32. When this configuration is employed, a first insulating layer 24A having opening portions is formed next on the first-principal-surface side of the n-side underlying conductive layer 40A formed from a transparent electrode layer. Similarly, a second insulating layer 34A having opening portions is formed on the second-principal-surface side of the p-side underlying conductive layer 50A formed from a transparent electrode layer. In the step of forming plating layers described above, electricity is fed from the side of the n-side underlying conductive layer 40A formed from a transparent electrode layer, and an electric potential is applied so that the electric potential of the p-side underlying conductive layer 50A with respect to the n-side underlying conductive layer 40A is equal to or higher than a forward drop voltage. This causes an electric current to flow to the p-side underlying conductive layer 50A via a diode that includes the n-side underlying conductive layer 40A and the p-side underlying conductive layer 50A. As a result, with the electricity fed from the side of the n-side underlying conductive layer 40A, a first plating layer 60A is formed on an exposed surface of the n-side underlying conductive layer 40A and a second plating layer 70A is formed on an exposed surface of the p-side underlying conductive layer 50A.

In the example illustrated in FIG. 10, a diode that includes the n-type semiconductor portion 20A and the p-type semiconductor portion 30A may have a PN junction or a PIN junction.

In the example described above with reference to FIG. 3 and other drawings, the n-type semiconductor portion 20 is formed on the first-principal-surface side of the semiconductor substrate 10, whereas the p-type semiconductor portion 30 is formed on the second-principal-surface side of the semiconductor substrate 10. However, the present disclosure is not limited to this example.

For instance, a so-called back contact-type configuration may be employed in which, as illustrated in FIG. 11, an n-type semiconductor portion 20B and a p-type semiconductor portion 30B are formed on the first-principal-surface side (back side in this example) of a semiconductor substrate 10B. When this configuration is employed, an n-side underlying conductive layer 40B and a p-side underlying conductive layer 50B are formed on the first-principal-surface side in the n-type semiconductor portion 20B. The n-side underlying conductive layer 40B and the p-side underlying conductive layer 50B may be formed by the same method that is described above as a method to be used in the steps of forming the n-side underlying conductive layer 40 and the p-side underlying conductive layer 50. In a subsequent step of forming plating layers, electricity fed from the side of the n-side underlying conductive layer 40B is used to apply an electric potential so that the electric potential of the p-side underlying conductive layer 50B with respect to the n-side underlying conductive layer 40B is equal to or higher than a forward drop voltage. This causes an electric current to flow to the p-side underlying conductive layer 50B via a diode that includes the n-side underlying conductive layer 40B and the p-side underlying conductive layer 50B. Asa result, with the electricity fed from the side of the n-side underlying conductive layer 40B, plating layers are formed on an exposed surface of the n-side underlying conductive layer 40B and an exposed surface of the p-side underlying conductive layer 50B at the same time.

In the example illustrated in FIG. 11, a diode that includes then-type semiconductor portion 20B and the p-type semiconductor portion 30B may have a PN junction or a PIN junction. That is, a configuration in which an intrinsic semiconductor portion 72 is interposed between the semiconductor substrate 10B and the n-type semiconductor portion 20B and an intrinsic semiconductor portion 74 is interposed between the semiconductor substrate 10B and the p-type semiconductor portion 30B may be employed.

Further, in the example illustrated in FIG. 11, a first plating layer 60B, which is formed on an exposed surface of the n-side underlying conductive layer 40B, is formed faster than a second plating layer 70B, which is formed on an exposed surface of the p-side underlying conductive layer 50B, in the step of forming the first plating layer 60B and the second plating layer 70B because electricity is fed from the side of the n-side underlying conductive layer 40B. The first plating layer 60B is consequently thicker than the second plating layer 70B. It is accordingly preferred to form the n-side underlying conductive layer 40B thinner than the p-side underlying conductive layer 50B in the steps of forming the n-side underlying conductive layer 40B and the p-side underlying conductive layer 50B. This thickness relationship reduces the difference in thickness between the bus bar electrodes, which include the first plating layer 60B and the n-side underlying conductive layer 40B, and the bus bar electrodes, which include the second plating layer 70B and the p-side underlying conductive layer 50B.

Note that, in the back contact-type configuration illustrated in FIG. 11, there may be employed a configuration in which an n-side underlying conductive layer 40B is formed from a transparent electrode layer on the first-principal-surface side of an n-type semiconductor portion 20B, and a p-side underlying conductive layer 50B is formed from a transparent electrode layer on the second-principal-surface side of a p-type semiconductor portion 30B.

1. A method of manufacturing a photoelectric conversion element, comprising the steps of:
preparing a semiconductor substrate including an n-type semiconductor portion and a p-type semiconductor portion, which forms a diode together with the n-type semiconductor portion;
forming an n-side underlying conductive layer on at least a part of the n-type semiconductor portion;
forming a p-side underlying conductive layer on at least a part of the p-type semiconductor portion;
immersing the n-side underlying conductive layer and the p-side underlying conductive layer in a plating solution; and
forming plating layers on at least a part of the n-side underlying conductive layer and at least a part of the p-side underlying conductive layer by feeding electricity to the n-side underlying conductive layer, under a state in which the n-side underlying conductive layer and the p-side underlying conductive layer are electrically connected by the diode alone.

2. The method of manufacturing the photoelectric conversion element according to claim 1,
wherein the photoelectric conversion element has a first principal surface and a second principal surface opposed to the first principal surface,
wherein the n-type semiconductor portion is formed on the first-principal-surface side of the semiconductor substrate,
wherein the p-type semiconductor portion is formed on the second-principal-surface side of the semiconductor substrate,
wherein, in the step of forming the n-side underlying conductive layer, the n-side underlying conductive layer is formed on the first-principal-surface side of the n-type semiconductor portion,
wherein, in the step of forming the p-side underlying conductive layer, the p-side underlying conductive layer is formed on the second-principal-surface side of the p-type semiconductor portion, and
wherein, in the step of forming the plating layers, the plating layers are formed on the first-principal-surface side of the n-side underlying conductive layer and the second-principal-surface side of the p-side underlying conductive layer.

3. The method of manufacturing the photoelectric conversion element according to claim 1, wherein the n-type semiconductor portion and the p-type semiconductor portion are formed on the same principal-surface side of the semiconductor substrate.

4. The method of manufacturing the photoelectric conversion element according to claim 1, wherein, in the step of forming the n-side underlying conductive layer, the n-side underlying conductive layer is formed using a transparent electrode layer.

5. The method of manufacturing the photoelectric conversion element according to claim 1, wherein, in the step of forming the p-side underlying conductive layer, the p-side underlying conductive layer is formed using a transparent electrode layer.

6. The method of manufacturing the photoelectric conversion element according to claim 1,
wherein, in the step of forming the p-side underlying conductive layer, the p-side underlying conductive layer is formed thicker than the n-side underlying conductive layer, or
wherein, in the step of forming the n-side underlying conductive layer, the n-side underlying conductive layer is formed thinner than the p-side underlying conductive layer.

7. The method of manufacturing the photoelectric conversion element according to claim 1, wherein, in the step of forming the plating layers, the plating layer to be formed on the n-side underlying conductive layer is formed thicker than the plating layer to be formed on the p-side underlying conductive layer.

8. The method of manufacturing the photoelectric conversion element according to claim 1,
wherein, in the step of preparing the semiconductor substrate, the semiconductor substrate having an intrinsic semiconductor portion between the n-type semiconductor portion and the p-type semiconductor portion is prepared, and
wherein the p-type semiconductor portion, the intrinsic semiconductor portion, and the n-type semiconductor portion form a PIN junction diode.

9. The method of manufacturing the photoelectric conversion element according to claim 1, further comprising, before the step of forming the n-side underlying conductive layer, a step of forming a first transparent electrode layer on the n-type semiconductor portion.

10. The method of manufacturing the photoelectric conversion element according to claim 1, further comprising, before the step of forming the p-side underlying conductive layer, a step of forming a second transparent electrode layer on the p-type semiconductor portion.

11. The method of manufacturing the photoelectric conversion element according to claim 1, further comprising, after the step of forming the n-side underlying conductive layer, a step of forming a first insulating layer on the n-type semiconductor portion.

12. The method of manufacturing the photoelectric conversion element according to claim 1, further comprising, after the step of forming the p-side underlying conductive layer, a step of forming a second insulating layer on the p-type semiconductor portion.

13. A photoelectric conversion element, comprising:
a semiconductor substrate including an n-type semiconductor portion and a p-type semiconductor portion, which forms a diode together with the n-type semiconductor portion;
an n-side underlying conductive layer provided on at least a part of the n-type semiconductor portion;
a p-side underlying conductive layer provided on at least a part of the p-type semiconductor portion;
a first plating layer provided on at least a part of the n-side underlying conductive layer; and
a second plating layer provided on at least a part of the p-side underlying conductive layer,
wherein the first plating layer being thicker than the second plating layer, and
wherein the n-side underlying conductive layer being thinner than the p-side underlying conductive layer.

14. The photoelectric conversion element according to claim 13,
wherein the photoelectric conversion element has a first principal surface and a second principal surface opposed to the first principal surface,
wherein the n-type semiconductor portion is provided on the first-principal-surface side of the semiconductor substrate,
wherein the p-type semiconductor portion is provided on the second-principal-surface side of the semiconductor substrate,
wherein the n-side underlying conductive layer is provided on the first-principal-surface side of the n-type semiconductor portion,
wherein the p-side underlying conductive layer is provided on the second-principal-surface side of the p-type semiconductor portion,
wherein the first plating layer is provided on the first-principal-surface side of the n-side underlying conductive layer, and
wherein the second plating layer is provided on the second-principal-surface side of the p-side underlying conductive layer.

15. The photoelectric conversion element according to claim 13, wherein the n-type semiconductor portion and the p-type semiconductor portion are provided on the same principal-surface side of the semiconductor substrate.

16. The photoelectric conversion element according to claim 13, wherein the n-side underlying conductive layer includes a transparent electrode layer.

17. The photoelectric conversion element according to claim 13, wherein the p-side underlying conductive layer includes a transparent electrode layer.

18. The photoelectric conversion element according to claim 13,
wherein the semiconductor substrate has an intrinsic semiconductor portion between the n-type semiconductor portion and the p-type semiconductor portion, and
wherein the p-type semiconductor portion, the intrinsic semiconductor portion, and the n-type semiconductor portion form a PIN junction diode.

19. The photoelectric conversion element according to claim 13, further comprising a first transparent electrode layer, which is provided between the n-side underlying conductive layer and the n-type semiconductor portion.

20. The photoelectric conversion element according to claim 13, further comprising a second transparent electrode layer, which is provided between the p-side underlying conductive layer and the p-type semiconductor portion.

21. The photoelectric conversion element according to claim 19, further comprising a first insulating layer, which is provided on the first transparent electrode layer.

22. The photoelectric conversion element according to claim 20, further comprising a second insulating layer, which is provided on the second transparent electrode layer.
